(19) United States
(12) Patent Application Publication
(10) Pub. No.: US 2026/0147015 A1
(43) Pub. Date: May 28, 2026

(54) TEST SOCKET AND TEST PROBE OF A MINIATURIZED PACKAGE-ON-PACKAGE DEVICE

(71) Applicants: Po-Jung Yeh, Taoyuan City (TW); Cheng-Jung Chien, Taoyuan City (TW)

(72) Inventors: Po-Jung Yeh, Taoyuan City (TW); Cheng-Jung Chien, Taoyuan City (TW)

(21) Appl. No.: 18/961,384

(22) Filed: Nov. 26, 2024

(51) Int. Cl. G01R 1/04; G01R 1/067; G01R 31/28

(52) U.S. Cl. CPC G01R 1/0466; G01R 1/06722; G01R 31/2886

(57) ABSTRACT

A test socket and a test probe of a miniaturized package-on-package are provided. The test socket includes a first testing base, including a first groove accommodating a plurality of single-active probes at a center of the first groove, a first bottom part and a second bottom part disposed from a wall of the first testing base toward the plurality of single-active probes; wherein the first bottom part has a guiding plate extending from the first bottom part in a height direction, and the second bottom part is adjacent to the plurality of single-active probes; and a second testing base, having a second insertion portion for inserting into the first groove of the first testing base; wherein the second insertion portion has the plurality of single-active probes corresponding to the plurality of single-active probes of the first testing base.

### FIELD OF THE DISCLOSURE

The present disclosure relates to a chip testing technology field, and more particularly to a test probe and a test probe of a miniaturized package-on-package (PoP) device.

### BACKGROUND OF THE DISCLOSURE

In recent years, with the miniaturization of electronic products, high-density packaging technology has become increasingly popular, among which Package-on-Package (PoP) technology has attracted the most attention. Package-on-package technology has advanced wafer thinning and related packaging technologies to stack multiple components vertically, integrating logic components in the bottom package and memory in the top package to provide a complete memory system.

Therefore, the technology has the advantage of being miniaturized and simplifying circuit board design. However, the requirements for high-speed and high-precision test sockets have become increasingly critical due to miniaturization and high-density packaging technology.

### SUMMARY OF THE DISCLOSURE

In response to the above-referenced technical inadequacies, the present disclosure provides a test socket and a test probe of a miniaturized package-on-package (PoP) device.

To achieve the objectives mentioned above, a test socket of a miniaturized package-on-package device is provided. The test socket includes: a first testing base, including a first groove accommodating a plurality of single-active probes at a center of the first groove, a first bottom part and a second bottom part disposed from a wall of the first testing base toward the plurality of single-active probes; wherein the first portion has a guiding plate extending from the first portion in a height direction, and the second portion is adjacent to the plurality of single-active probes; wherein the thickness of the guide plate is 1.45 mm; and a second testing base, having a second insertion portion inserting in the first groove of the first testing base; wherein the second insertion portion has the plurality of single-active probes corresponding to the plurality of single-active probes of the first testing base; wherein the total length of each of the plurality of single-active probes is between 1.4 mm and 2 mm; wherein a bottom side of the second insertion portion has a first abutting part and a second abutting part corresponding to the first bottom part and the second bottom part; wherein the thickness between the first abutting part and the accommodation space is 0.6 mm.

Furthermore, a test probe is provided to achieve the objectives mentioned above. The test probe includes a single-active probe having a hollow tube body, and an elastic member disposed in the hollow tube body; wherein two ends of the elastic member are respectively connected to a detecting contact and an electrical contact; wherein the end of the detecting contact contacts a component under test, and the end of the electrical contact contacts a load board; wherein the total length of the single-active probes is between 1.4 mm and 2 mm.

### BRIEF DESCRIPTION OF THE DRAWINGS

The described embodiments may be better understood by reference to the following description and the accompanying drawings in which:

FIG. 1 is an exploded perspective schematic view of the first testing base and the second testing base of the present disclosure;

FIG. 2 is an assembled perspective schematic view of the first testing base and the second testing base of the present disclosure;

FIG. 3 is a partially enlarged schematic view of the present disclosure;

FIG. 4 is a perspective view of the single-active probe of the present disclosure;

FIG. 5 is a sectional schematic view of line V-V of FIG. 4 of the present disclosure;

FIG. 6 is a schematic view of the movement according to FIG. 5 of the present disclosure; and

FIG. 7 is an exploded perspective schematic view of the first testing base and another second testing base of the present disclosure.

### DETAILED DESCRIPTION OF THE EXEMPLARY EMBODIMENTS

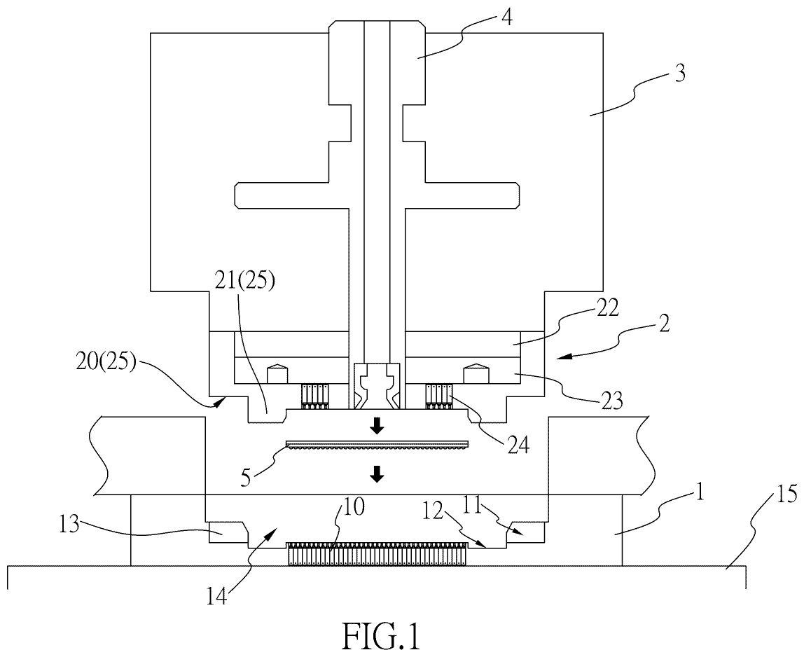

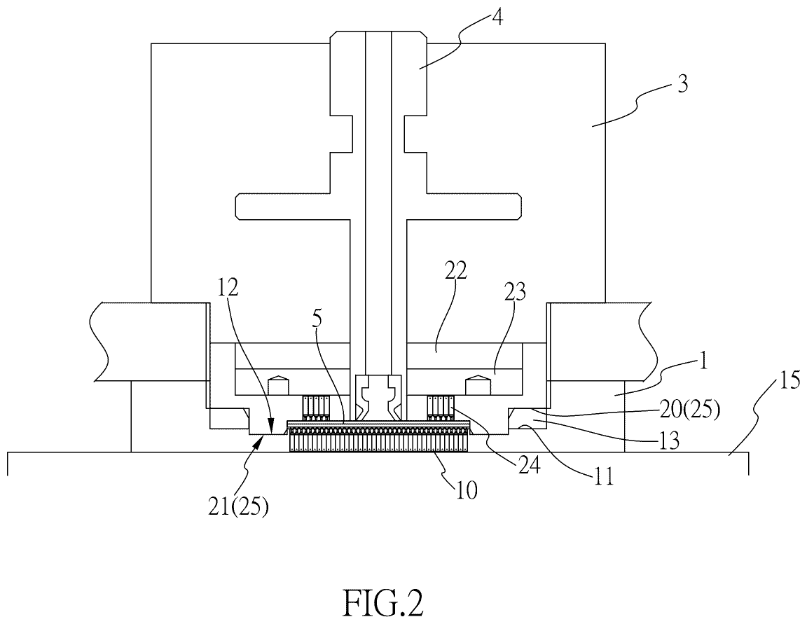

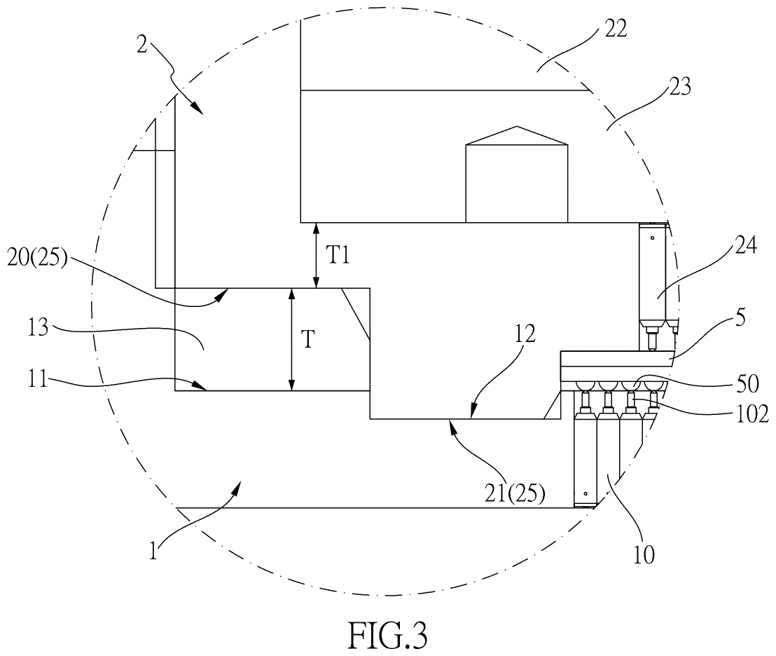

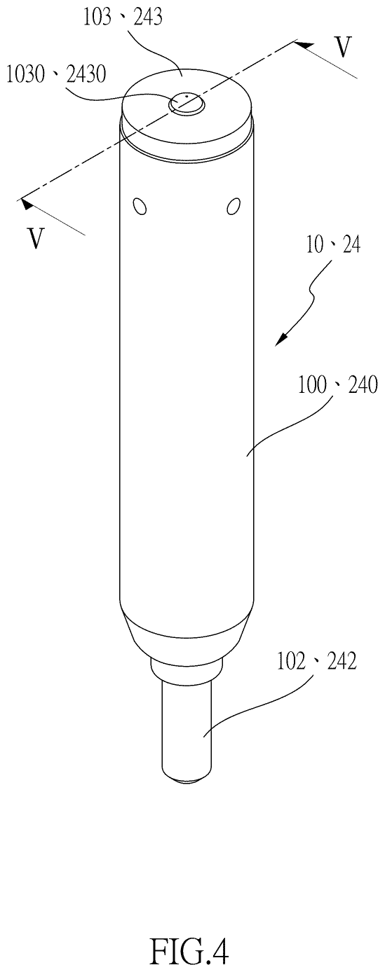

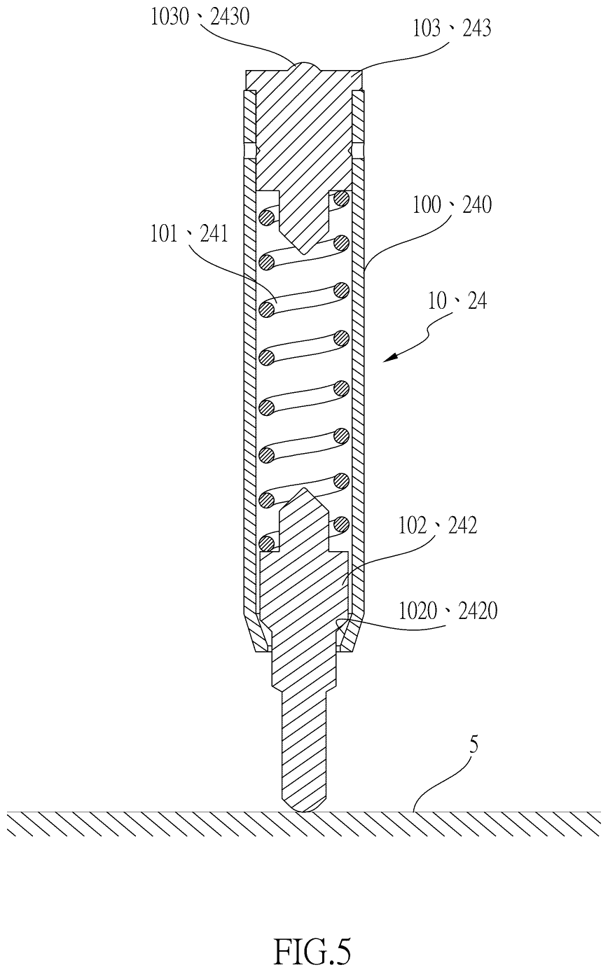

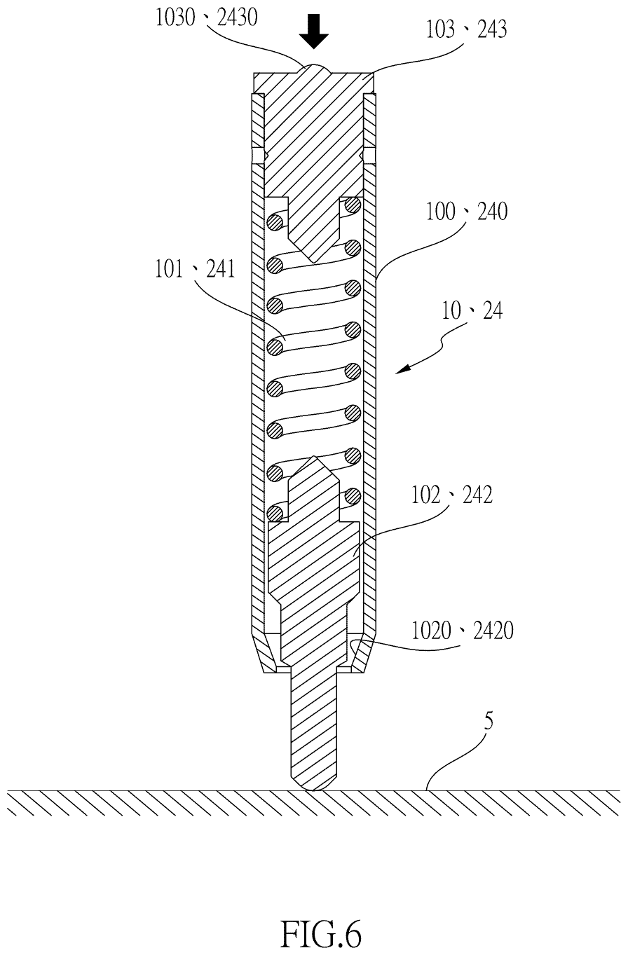

Referring to FIGS. 1-6, the present disclosure provides a test probe and a test probe of a miniaturized package-on-package (PoP) device. The test socket includes a first testing base 1 and a second testing base 2.

The first testing base 1 includes a first groove 14 accommodating a plurality of single-active probes 10 at a center of the first groove 14. A first bottom part 11 and a second bottom part 12 are disposed from a wall of the first testing base 1 toward the direction of the plurality of single-active probes 10. The first bottom part 11 is higher than the second bottom part 12 and has a guiding plate 13 on the surface, and the second bottom part 12 is adjacent to the plurality of single-active probes 10.

The second testing base 2 has a second insertion portion 25 for inserting into the first groove 14 of the first testing base 1. The second insertion portion 25 has a plurality of single-active probes 24 corresponding to the plurality of single-active probes 10 of the first testing base 1. Further, a bottom side of the second insertion portion 25 has a first abutting part 20 and a second abutting part 21 corresponding to the first bottom part 11 and the second bottom part 12.

In one embodiment of the present disclosure, an integrated circuit component testing machine 3 is disposed above the second testing base 2, and an accommodating space 22 is between the second testing base 2 and the bottom of the integrated circuit component testing machine 3. An adapter board 23 is provided in the accommodating space 22, and the second testing base 2 further includes a suction nozzle shaft 4 passing through the integrated circuit component testing machine 3 and the second insertion portion 25.

In detail, the single-active probe 10, 24 of the first testing base 1 and the second testing base 2 has a hollow tube body 100, 240, and an elastic member 101, 241 disposed in the hollow tube body 100, 240. Two ends of the elastic member 101, 241 are respectively connected to a detecting contact 102, 242 and an electrical contact 103, 243. The end of the detecting contact 102, 242 contacts a chip 5. The end of the electrical contact 103, 243 has a hemispherical contact point 1030, 2430.

In one embodiment of the present disclosure, the present disclosure performs a Final Test (FT) on the chip 5 to determine whether there is any bad signal during the chip packaging process, the first testing base 1 is disposed on the load board 15. Further, the chip 5 is placed on the single-active probes 10, and the leads 50 of the chip 5 (such as solder balls or pins or conductive pads) are electrically connected to the detecting contacts 102 of the single-active probes 10.Then, the second insertion portion 25 of the second testing base 2 is inserted into the first groove 14 of the first testing base 1, so that the first abutting part 20 and the second abutting part 21 of the second insertion portion 25 are respectively abutted the guide plate 13 of the first bottom part 11 and the upper part of the second bottom part 12, and then the chip 5 is positioned by the suction nozzle shaft 4. During the test process, the second testing base 2 continuously presses down, causing the detecting contacts 102, 242 of the single-active probes 10, 24 to simultaneously compress the elastic members 101, 241 inside the hollow tube bodies 100, 240. The detecting contacts 102, 242 have a restoring pre-force through the elastic members 101, 241.

Moreover, the hollow tube body 100, 240 has a tapered portion 1020, 2420 at an end corresponding to the detecting contact 102, 242; wherein the diameter of the tapered portion 1020, 2420 is smaller than the diameter of the detecting contact 102, 242, so that the detecting contact 102, 242 can elastically extend out of the hollow tube body 100, 240 without falling out. At the same time, the elastic members 101, 241 will also squeeze the electrical contacts 103, 243 to ensure the electrical connection between the chip 5 and the load board 15 and avoid inaccurate testing of the single-active probes 10, 24. The electrical contact 103, 243 utilizes the contact point 1030, 2430 to increase the contact area and reduce the pressure per unit area.

In addition, it is worth mentioning that in order to meet the requirements of chip miniaturization, higher DDR specification, and faster reading and writing speed, the thickness of the test socket needs to be thinner, and the length of the test probe also needs to be shorter. However, during the test process, the test socket will become thinner and, therefore, insufficient strength. Then, it will be easily bent and deformed by the elastic impact of the test probe.

To avoid the above problems, the thickness T of the guide plate 13 of the first testing base 1 is 1.45 mm, and the thickness T1 between the first abutting part 20 of the second insertion portion 25 and the accommodation space 22 is 0.6 mm. Furthermore, the total length L of the single-active probes 10, 24 is between 1.4 mm and 2 mm. When the total length L of the single-active probe 10, 24 meets the above conditions, it can not only meet the requirements of the higher DDR specifications, but also ensure that the single-active probe 10, 24 has sufficient elasticity, and the effect of less pre-loaded elasticity is achieved without changing the compression process.

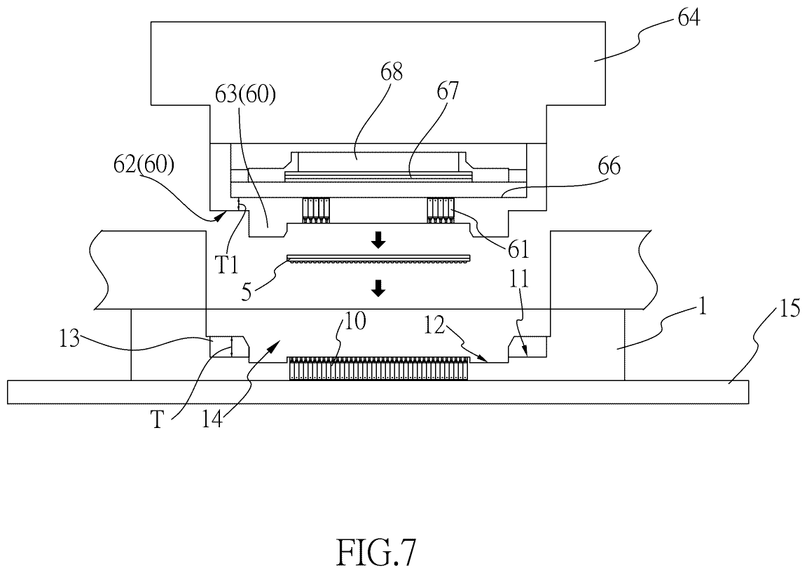

In addition, referring to FIG. 7, when the present disclosure performs a System Level Testing (SLT) on the chip 5, another embodiment of the second testing base 6 is applied. The second testing base 6 has a second insertion portion 60 for inserting into the first groove 14 of the first testing base 1. The second insertion portion 60 has a plurality of single-active probes 61 corresponding to the plurality of single-active probes 10 of the first testing base 1. Further a bottom side of the second insertion portion 60 has a first abutting part 62 and a second abutting part 63 corresponding to the first bottom part 11 and the second bottom part 12 of the first testing base 1.

In one embodiment of the present disclosure, the second testing base 6 has an integrated circuit component testing machine 64 disposed above the second insertion portion 60, and an accommodating space 65 is between the second insertion portion 60 and the bottom of the integrated circuit component testing machine 64. The accommodation space 65 is provided with an adapter board 66, a dynamic random-access memory 67, and a foam 68.

During the test of the chip 5, in order to prevent the test socket from being bent and deformed due to the thin thickness of the test socket, coupled with the elastic impact from the test probe. In one embodiment of the present disclosure, the thickness T of the guide plate 13 of the first testing base 1 is 1.45 mm. Further, the thickness T1 between the first abutting part 62 of the second insertion portion 60 and the accommodation space 65 is 0.6 mm. Furthermore, the total length L of the single-active probes 10, 24 is between 1.4 mm and 2 mm. System Level Testing (SLT) is not a technical feature in the present disclosure. Therefore, it is no longer described in detail herein.

What is claimed is:

1. A test socket of a miniaturized package-on-package device, comprising:
a first testing base, including a first groove accommodating a plurality of single-active probes at a center of the first groove, a first bottom part and a second bottom part disposed from a wall of the first groove toward the plurality of single-active probes; wherein the first bottom part has a guiding plate extending from the first bottom part in a height direction, and the second bottom part is adjacent to the plurality of single-active probes; wherein the thickness of the guide plate is 1.45 mm; and
a second testing base, having a second insertion portion inserting in the first groove of the first testing base and an accommodating space; wherein the second insertion portion has the plurality of single-active probes corresponding to the plurality of single-active probes of the first testing base; wherein the total length of each of the plurality of single-active probes is between 1.4 mm and 2 mm; wherein a bottom side of the second insertion portion has a first abutting part and a second abutting part corresponding to the first bottom part and the second bottom part; wherein the thickness between the first abutting part and the accommodation space is 0.6 mm.

2. The test socket of a miniaturized package-on-package device according to claim 1, wherein the first bottom part and the second bottom part are arranged in a stair-step configuration.

3. The test socket of a miniaturized package-on-package device according to claim 1, wherein a load board is disposed on a bottom side of the first testing base.

4. The test socket of a miniaturized package-on-package device according to claim 1, wherein each of the plurality of single-active probes has a hollow tube body with an elastic member, and two ends of the elastic member are respectively connected to a detecting contact and an electrical contact.

5. The test socket of a miniaturized package-on-package device according to claim 4, wherein an end of the electrical contact of each of the plurality of single-active probes has a hemispherical contact point.

6. The test socket of a miniaturized package-on-package device according to claim 4, wherein the hollow tube body of the single-active probe has a tapered portion at an end corresponding to the detecting contact; wherein the diameter of the tapered portion is smaller than the diameter of the detecting contact, so that the detecting contact can elastically extend out of the hollow tube body without falling out.

7. The test socket of a miniaturized package-on-package device according to claim 1, wherein an integrated circuit component testing machine is disposed above the second testing base, and an adapter board is provided in the accommodating space of the second testing base; wherein the second testing base further includes a suction nozzle shaft passing through the integrated circuit component testing machine and the second insertion portion.

8. A test probe of a miniaturized package-on-package device, comprising: a single-active probe, has a hollow tube body, and an elastic member disposed in the hollow tube body; wherein two ends of the elastic member are respectively connected to a detecting contact and an electrical contact;
wherein the end of the detecting contact contacts a component under test, and the end of the electrical contact contacts a load board;
wherein the total length of the single-active probes is between 1.4 mm and 2 mm.

9. The test probe of a miniaturized package-on-package device according to claim 8, wherein the end of the electrical contact of each of the plurality of single-active probes has a hemispherical contact point.

10. The test probe of a miniaturized package-on-package device according to claim 8, wherein the hollow tube body of the single-active probe has a tapered portion at an end corresponding to the detecting contact; wherein the diameter of the tapered portion is smaller than the diameter of the detecting contact, so that the detecting contact can elastically extend out of the hollow tube body without falling out.
